(19) United States
(12) Patent Application Publication
(10) Pub. No.: US 2013/0015838 A1
(43) Pub. Date: Jan. 17, 2013

(54) DOCUMENT SIZE DETECTING DEVICE AND MULTI-FUNCTION PERIPHERAL

(71) Applicant: Hung-Wei Liao, New Taipei City (TW)

(72) Inventor: Hung-Wei Liao, New Taipei City (TW)

(73) Assignees: Cal-Comp Electronics & Communications Company Limited, New Taipei City (TW); KINPO ELECTRONICS, INC., New Taipei City (TW)

(21) Appl. No.: 13/244,287

(22) Filed: Sep. 24, 2011

(30) Foreign Application Priority Data
Jul. 14, 2011 (TW) 100124948

(51) Int. Cl. G01R 19/00

(52) U.S. Cl. 324/76.11

(57) ABSTRACT

A document size detecting device and multi-function peripheral are provided. The multi-function peripheral includes a body, a tray and a document size detecting device. The tray is disposed on the body, and the document size detecting device is disposed on the tray. The document size detecting device includes a size adjusting unit, a pressing element, a circuit board and a film. The size adjusting unit is disposed on the tray and the pressing element is disposed on the size adjusting unit. The circuit board is disposed on the tray and by the size adjusting unit. The circuit board has first pads and the film disposed on the circuit board has second pads corresponding to the first pads. The pressing element presses on the film, such that the second pad under the pressing element contacts one of the first pads to generate a detecting signal transmitting to the body.

### CROSS-REFERENCE TO RELATED APPLICATION

This application claims the priority benefit of Taiwan application serial no. 100124948, filed on Jul. 14, 2011. The entirety of the above-mentioned patent application is hereby incorporated by reference herein and made a part of this specification.

### BACKGROUND OF THE DISCLOSURE

1. Field of the Application

The present invention relates to a document size detecting device and a multi-function peripheral. More particularly, the present invention relates to a document size detecting device and a multi-function peripheral having the capability to effectively reduce the fabrication cost.

2. Description of Related Art

In general, a document size of A4 is commonly used in a multi-function peripheral and thus the trays for paper inlet and paper outlet of the automatic paper feeding devices are specially designed to fit the A4 document size. In such configuration, it is unnecessary to dispose the document size detecting device. However, with the demands of users different document sizes are necessary to feed into the paper feeding device. Thus, it necessitates the deposing of the document size detecting device so as to detect the size of the document to be scanned or printed.

FIG. 1 schematically illustrates a conventional document size detecting device. Referring to FIG. 1, the first paper stopping slice 1201, the first rack 1202 and the rib 1203 in the first paper guide plate 120 are integrally formed. The first rack 1202 is engaged with the rack movement mechanism 170. The sensing members 180, 181 are disposed beside the rack movement mechanism and having a first optical emitter 1801, the first optical receiver 1802, the second optical emitter 1811 and the second optical receiver 1812.

When a document has to be scanned or printed, the user may place the paper in the paper inlet tray and move the first paper guide plate 120 so that the distance between the first paper guide plate 120 and the second guide plate is equal to the width of the paper. At the same time when the first paper guide plate 120 is moved, the rib 1203 in the first paper guide plate 120 will also move along with the movement of the first paper guide plate 120 and pass through between the first optical emitter 1801 and the first optical receiver 1802 of the first sensing member 180 and obstruct the light emitted by the first optical emitter 1801. In the meantime, the first optical receiver 1802 cannot receive the light and output the size of the detected document, such that the document size detecting device 110 may not know the document size.

Therefore, it would have increased the number of the sensing members and results the increase of the cost of the multi-function peripheral, if the multi-function peripheral has to provide a diversified printing document sizes.

### SUMMARY OF THE INVENTION

The present invention provides a document size detecting device of which the structure is simple.

The present invention provides a multi-function peripheral capable to automatically adjust the printing parameters.

A document size detecting device adapted to mount on a carrier to detect the document size carried by the carrier is provided in the present invention. The document size detecting device includes a size adjusting unit, a pressing element, a circuit board and a film. Herein the size adjusting unit is disposed on the carrier and adapted to move related to the carrier. The pressing element is disposed on the size adjusting unit to move along with the size adjusting unit. The circuit board is disposed on the carrier and located beside the size adjusting unit, and has a plurality of first pads. The film is disposed on the circuit board, having a plurality of second pads, wherein the second pads are opposing to the first pads. The pressing element presses the film so that one of the second pads contacts the corresponding first pad to generate a detecting signal.

In one embodiment of the present invention, the size adjusting unit includes a gear and a pair of gear racks. The gear is pivoted to the carrier. The gear racks are coupled to the gear and taking the gear as the center of symmetry and symmetrically disposed beside the opposite sides of the gear. And the pressing element is disposed on one of the gear racks.

In one embodiment of the present invention, the pressing element is an elastic element.

In one embodiment of the present invention, the film has a first strain layer and a second strain layer. And the first strain layer is located between the circuit board and the second strain layer and has a plurality of openings. And the second pads are located at the second strain layer, and the second pads are correspondingly located in the openings. Herein the film is folded so as to form the first strain layer and the second strain layer. Or the first strain layer is a film and the second strain is a film respectively.

In one embodiment of the present invention, the pressing element has a protrusion to contact with the film.

The present invention further provides a multi-function peripheral including a body, a tray and a document size detecting device. Herein the tray is disposed in the body. The document size detecting device is disposed on the tray to detect the size of the document carried by the tray. The document size detecting device includes a size adjusting unit, a pressing element, a circuit board and a film. The document size detecting device is mounted on the tray and adapted to move related to the tray. And the pressing element is disposed on the size adjusting unit so as to move along with the size adjusting unit. The circuit board is disposed on the tray and located beside the size adjusting unit, and has a plurality of first pads. The film is disposed on the circuit board, having a plurality of second pads, wherein the second pads are opposing to the first pads. The pressing element presses the film so that one of the second pads contacts the corresponding first pad to generate a detecting signal and transmit the detecting signal to the body.

In one embodiment of the present invention, the size adjusting unit includes a gear and a pair of gear racks. The gear is pivoted to the tray. The gear racks are coupled to the gear and taking the gear as the center of symmetry and symmetrically disposed beside the opposite sides of the gear. And the pressing element is disposed on one of the gear racks.

In one embodiment of the present invention, the pressing element is an elastic element.

In one embodiment of the present invention, the film has a first strain layer and a second strain layer. And the first strain layer is located between the circuit board and the second strain layer and has a plurality of openings. And the second pads are located at the second strain layer, and the second pads are correspondingly located in the openings. The film is folded so as to form the first strain layer and the second strain layer. The first strain layer is a film and the second strain is a film respectively.

In one embodiment of the present invention, the pressing element has a protrusion to contact with the film.

In one embodiment of the present invention, the tray is located in the body and adapted to be pulled out of the body.

In one embodiment of the present invention, the tray is pivoted to the body and adapted to open related to the body.

In light of the above, in the document size detecting device of the present invention, a pressing element is disposed on the size adjusting unit, and with collocation of the utilizing of film and circuit board, such that a detecting signal can be generated corresponding to the location of the size adjusting unit when the film touches the pad of the circuit board and when the pressing element presses the film. Since the document size detecting device of the present invention is much simpler in structure compared with the conventional document size detecting device, the fabrication cost can be effectively reduced. And by utilizing the document size detecting device of the present invention, the multi-function peripheral can also obtain the real time printing parameters of the document so as to proceed with the printing process.

In order to make the aforementioned and other features and advantages of the invention more comprehensible, embodiments accompanying figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 schematically illustrates a conventional document size detecting device.

FIG. 2 is a schematic view of a multi-function peripheral according to an embodiment of the present invention.

FIG. 3 is a schematic view illustrating a document size detecting device and a tray of the multi-function peripheral in FIG. 2.

FIG. 4 is an enlarged partial view of FIG. 3.

FIG. 5 is a schematic view of the circuit board and the film.

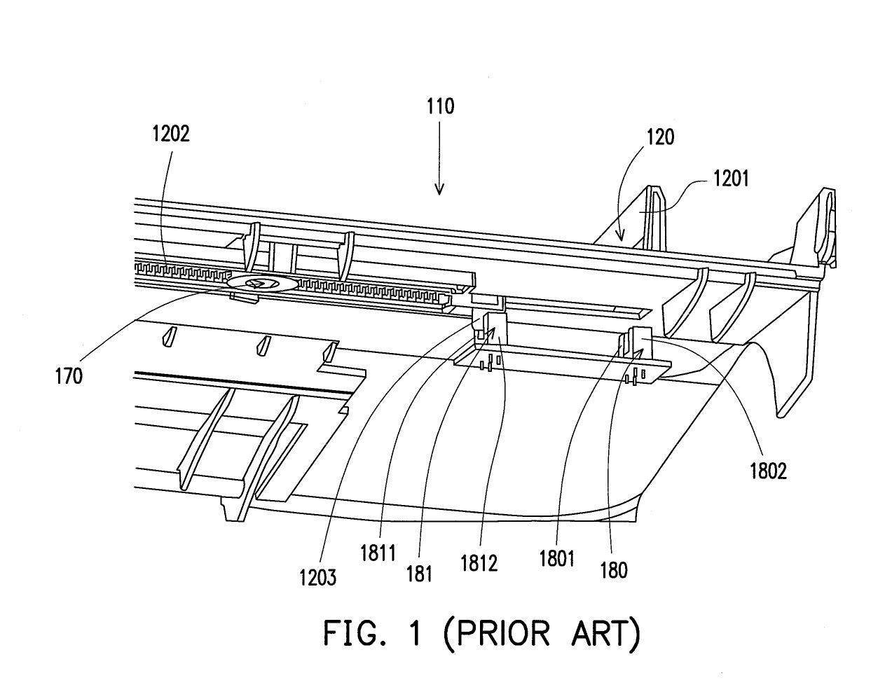

### DESCRIPTION OF EMBODIMENTS

A document size detecting device adapted to mount on a carrier to detect the document size carried by the carrier is provided in the present invention. The document size detecting device is simple in structure and thus adapted for using in the application of electronic devices such as multi-function peripheral so as to effectively reduce the fabrication cost. An example of using the document size detecting device in the application of the multi-function peripheral is described in the following.

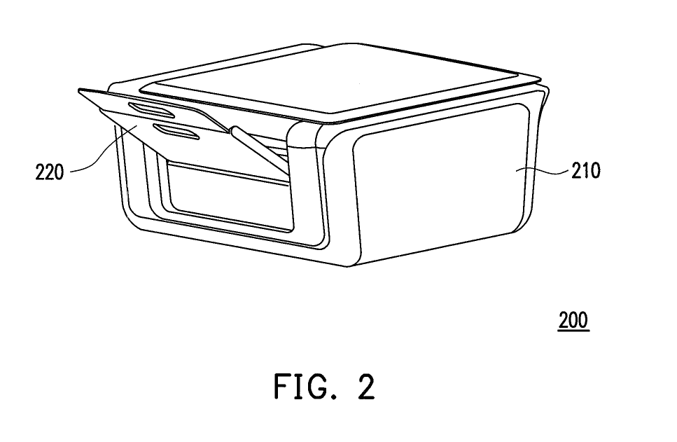

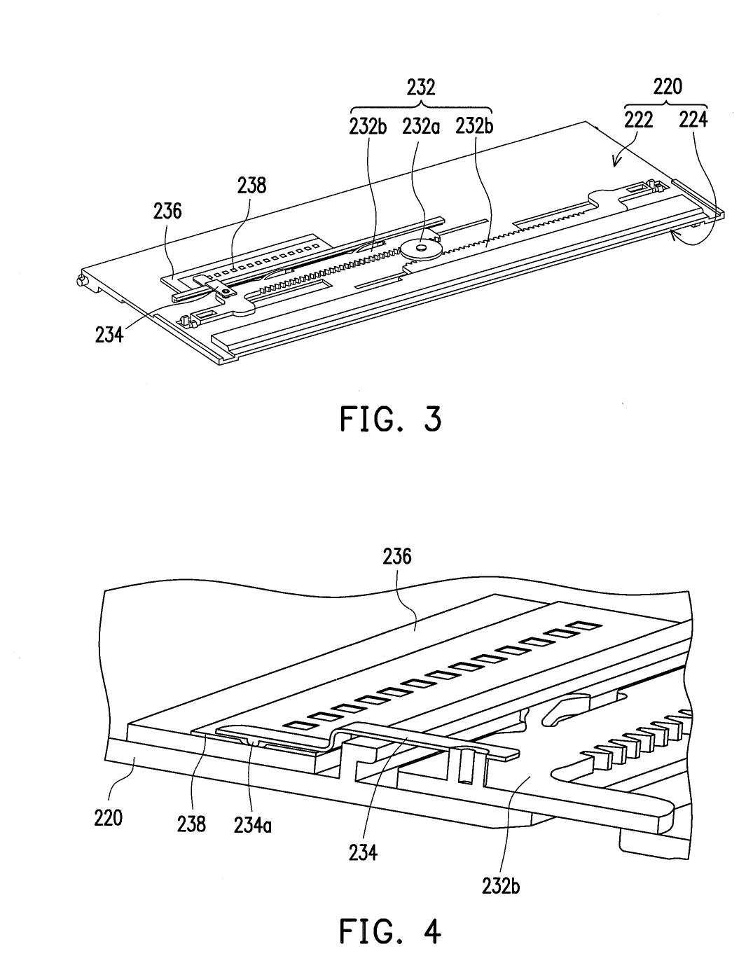

FIG. 2 is a schematic view of a multi-function peripheral according to an embodiment of the present invention. FIG. 3 is a schematic view illustrating a document size detecting device and a tray of the multi-function peripheral in FIG. 2. FIG. 4 is an enlarged partial view of FIG. 3. Please refer to FIG. 2, FIG. 3 and FIG. 4. The multi-function peripheral 200 includes a body 210, a tray 220 and a document size detecting device 230. Herein the tray 220 is disposed in the body 210 and paper 300 is adapted to be placed in the tray 220. The document size detecting device 230 is mounted on the tray 220 to detect the size of the paper 300 carried by the tray 220. The document size detecting device 230 includes a size adjusting unit 232, a pressing element 234, a circuit board 236 and a film 238. The document size detecting device 232 is mounted on the tray 220 and adapted to move related to the tray 220. And the pressing element 234 is disposed on the size adjusting unit 232 so as to move along with the size adjusting unit 232. The circuit board 236 is disposed on the tray 220 and located beside the size adjusting unit 232, and has a plurality of first pads 236a. The film 238 is disposed on the circuit board 236, having a plurality of second pads 238a, wherein the second pads 238a are opposing to the first pads 236a.

According to the present embodiment, the tray 220 is pivoted to the body 210 and adapted to open related to the body 210. In other embodiments (not shown), the tray 220 can be fixed within the body 210 such that users can pull the tray 220 out of the body 210.

In addition, the size adjusting unit 232 includes a gear 232a and a pair of gear racks 232b. The gear 232a is pivoted to the tray 220. The gear racks 232b are coupled to the gear 232a and taking the gear 232a as the center of symmetry and symmetrically disposed beside the opposite sides of the gear 232a by using the gear 232a as the center of symmetry. The pressing element 234 is disposed on one of the gear racks 232b. The pressing element 234 of the present embodiment is an elastic element such as a spring and has a protrusion 234a so that the film 238 may induce more strain as being pressed. The second pad 238a disposed on the film 238 contacts the first pad 236a disposed on the circuit board 236. Additionally, the size adjusting unit 232 and the pressing element 234 are disposed at the bottom 222 of the tray 220 which does not carry the paper 300 so as to avoid the paper feeding being obstructed. It has to be noted that, herein at least one gear rack 232b has a bump (not shown), and the bump protrudes at the top 224 of the tray 220 so as to carry the paper 300.

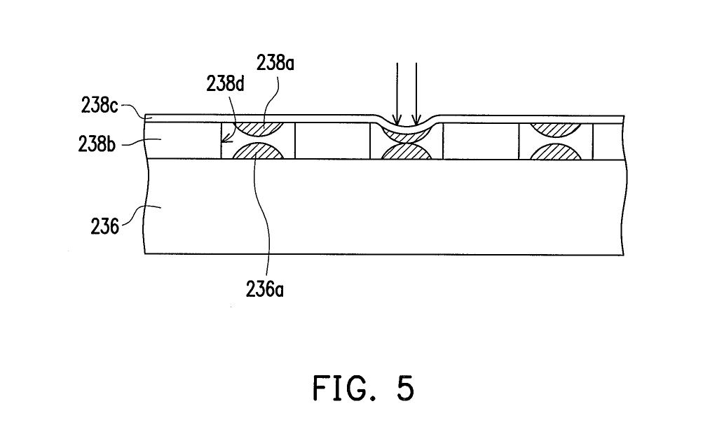

FIG. 5 is a schematic view of the circuit board and the film. Referring to FIG. 5, the film 238 has a first strain layer 238b and a second strain layer 238c. And the first strain layer 238b is located between the circuit board 236 and the second strain layer 238c and has a plurality of openings 238d. And the second pads 238a are located at the second strain layer 238c, and the second pads 238a are correspondingly located in the openings 238d. The first strain layer 238b and the second strain layer 238c can be formed by folding the film 238 or the first strain layer 238b is a single film and the second strain layer 238c is a single film respectively.

Please refer to FIG. 2 and FIG. 3. When the paper 300 is placed in the tray 220 and the user manually moves the bump (not shown) of the gear rack 232b protruding at the top 224 of the tray 220, then the gear rack 232b on which the bump is disposed will drive the gear 232a to rotate, and will further drive another gear rack 232b which is symmetrically disposed at another side of the gear 232a, the center of symmetry, to relatively be close or distant so as to fit the size of the paper 300.

Then, please refer to FIG. 2, FIG. 4 and FIG. 5. Especially, the protrusion 234 of the pressing element 234 disposed on the gear rack 232b may press the film 238, then the second strain layer 238c may deform toward the circuit board 236 because of being pressed. And then, the second pad 238a of the deformation point of the corresponding second strain layer 238c will contact with the corresponding first pad 236a, and a detecting signal will be generated. The detecting signal relates to the size of the paper 300, and the detecting signal may be transmitted to the body 210. Then, the body 210 may adjust the printing parameters of the document to be printed.

Furthermore, the document size detecting device 230 may transmit the real time signal of the size of the paper 300 to the body 210. Compared to the conventional multi-function peripheral in which the user has to use control programs to select the size of the paper 300 for printing parameters before the printing process, the multi-function peripheral 200 of the embodiment can transmit a real time signal of the size of the paper 300 to adjust the printing parameter so as to avoid the mismatch of the printing area and the paper 300.

In light of the foregoing, the document size detecting device of the present invention is much simpler in structure compared with the conventional document size detecting device, and thus the fabrication cost can be effectively reduced. Furthermore, by utilizing the document size detecting device of the present invention, the multi-function peripheral can also obtain the real time printing parameters of the document so as to proceed with the printing process and avoid the mismatch of the printing area and the document size. In addition, through the setting of the document size before the printing process and the real time signal of the document size transmitted by the document size detecting device, a double confirmation can be obtained to prevent the printing errors. And saving of printing papers and environmental protection can further be achieved.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A document size detecting device, adapted to mount on a carrier to detect a document size carried by the carrier, comprising:
a size adjusting unit disposed on the carrier and adapted to move related to the carrier;
a pressing element disposed on the size adjusting unit to move along with the size adjusting unit;
a circuit board disposed on the carrier and located beside the size adjusting unit, having a plurality of first pads; and
a film disposed on the circuit board, having a plurality of second pads, wherein the second pads are opposing to the first pads,
the pressing element pressing the film such that one of the second pads contacts with a corresponding first pad to generate a detecting signal.

2. The document size detecting device as claimed in claim 1, wherein the size adjusting unit comprises:
a gear, pivoted to the carrier; and
a pair of gear racks coupled to the gear and taking the gear as the center of symmetry and symmetrically disposed at the opposite sides of the gear, and the pressing element disposed on one of the gear racks.

3. The document size detecting device as claimed in claim 1, wherein the pressing element is an elastic element.

4. The document size detecting device as claimed in claim 1, wherein the film has a first strain layer and a second strain layer, and the first strain layer is located between the circuit board and the second strain layer and has a plurality of openings, and the second pads are located at the second strain layer, and the second pads are correspondingly located in the openings.

5. The document size detecting device as claimed in claim 4, wherein the film is folded so as to form the first strain layer and the second strain layer.

6. The document size detecting device as claimed in claim 4, wherein the first strain layer is a film and the second strain layer is a film respectively.

7. The document size detecting device as claimed in claim 1, wherein the pressing element has a protrusion and the protrusion contacts the film.

8. A multi-function peripheral, comprising:
a body;
a tray, disposed on the body;
a document size detecting device, mounted on the tray to detect a document size carried by the tray, comprising:
a size adjusting unit disposed on the tray and adapted to move related to the tray;
a pressing element disposed on the size adjusting unit to move along with the size adjusting unit;
a circuit board disposed on the tray and located beside the size adjusting unit, having a plurality of first pads; and
a film disposed on the circuit board, having a plurality of second pads, wherein the second pads are opposing to the first pads,
the pressing element pressing the film such that one of the second pads contacts with a corresponding first pad to generate a detecting signal and transmits the detecting signal to the body.

9. The multi-function peripheral as claimed in claim 8, wherein the size adjusting unit comprises:
a gear, pivoted to the tray; and
a pair of gear racks coupled to the gear and taking the gear as the center of symmetry and symmetrically disposed beside the opposite sides of the gear, and the pressing element disposed on one of the gear racks.

10. The multi-function peripheral as claimed in claim 8, wherein the pressing element is an elastic element.

11. The multi-function peripheral as claimed in claim 8, wherein the film has a first strain layer and a second strain layer, and the first strain layer is located between the circuit board and the second strain layer and has a plurality of openings, and the second pads are located at the second strain layer, and the second pads are correspondingly located in the openings.

12. The multi-function peripheral as claimed in claim 11, wherein the film is folded so as to form the first strain layer and the second strain layer.

13. The multi-function peripheral as claimed in claim 11, wherein the first strain layer is a film and the second strain layer is a film respectively.

14. The multi-function peripheral as claimed in claim 8, wherein the pressing element has a protrusion and the protrusion contacts the film.

15. The multi-function peripheral as claimed in claim 8, wherein the tray is located in the body and adapted to be pulled out of the body.

16. The multi-function peripheral as claimed in claim 8, wherein the tray is pivoted to the body and adapted to open related to the body.
